(19) United States
(12) Patent Application Publication
(10) Pub. No.: US 2013/0105204 A1
(43) Pub. Date: May 2, 2013

(54) CIRCUIT BOARD AND METHOD FOR MANUFACTURING THE SAME

(71) Applicants: Jenn-Chang HWANG, Hsinchu (TW); Chao-Ying HSIEH, Hsinchu (TW); Chwung-Shan KOU, Hsinchu (TW); Chung-Hwa WANG, Hsinchu (TW); Li-Shiuan TSAI, Hsinchu (TW); Lung-Kai MAO, Hsinchu (TW); Shih-Jie JIAN, Hsinchu (TW); Jian-You LIN, Hsinchu (TW); Chun-Yi LEE, Hsinchu (TW)

(72) Inventors: Jenn-Chang HWANG, Hsinchu (TW); Chao-Ying HSIEH, Hsinchu (TW); Chwung-Shan KOU, Hsinchu (TW); Chung-Hwa WANG, Hsinchu (TW); Li-Shiuan TSAI, Hsinchu (TW); Lung-Kai MAO, Hsinchu (TW); Shih-Jie JIAN, Hsinchu (TW); Jian-You LIN, Hsinchu (TW); Chun-Yi LEE, Hsinchu (TW)

(73) Assignee: National Tsing Hua University, Hsinchu (TW)

(21) Appl. No.: 13/417,869

(22) Filed: Mar. 12, 2012

(30) Foreign Application Priority Data
Nov. 2, 2011 (TW) 100139976

(51) Int. Cl. H05K 1/03; H05K 1/02; H05K 1/09; H05K 3/00

(52) U.S. Cl. 174/255; 29/829; 174/258; 174/257

(57) ABSTRACT

A circuit board and a method for manufacturing the same are disclosed. The circuit board of the present invention comprises: a carrier board, wherein a first circuit layer is disposed on at least one surface of the carrier board, and the first circuit layer comprises plural conductive pads; a protein dielectric layer disposed on the surface of the carrier board and the first circuit layer, wherein the protein dielectric layer has plural openings to expose the conductive pads; and a second circuit layer disposed on a surface of the protein dielectric layer, wherein the second circuit layer comprises plural first conductive vias, and each first conductive via is correspondingly formed in the opening and electrically connects to the conductive pad.

### CROSS REFERENCE TO RELATED APPLICATION

This application claims the benefits of the Taiwan Patent Application Serial Number 100139976, filed on Nov. 2, 2011, the subject matter of which is incorporated herein by reference.

### BACKGROUND OF THE INVENTION

1. Field of the Invention

The present invention relates to a circuit board and a method for manufacturing the same and, more particularly, to a circuit board and a method for manufacturing the same with a protein dielectric layer.

2. Description of Related Art

As the development of the electronic industry advances, demands for electronic products with multi-functions and high performance are increased. In order to integrate several active units and inactive units on one device, semiconductor-packaging technologies have been developed to package more circuits and electronic units in a limited area.

According to the conventional circuit boards, dielectric materials are used to electrically disconnect the circuit lines and the circuit layer. The dielectric materials generally used in the art can be photoreactive or non-photoreactive resins, such as ABF, bismaleimide/triazine, biphenylbutadiene, liquid crystal polymer, polyimide, poly(vinyl ether), poly(tetrafluoroethylene), aromatic nylon, epoxy resins or glass fibers; or material containing epoxy resins and glass fibers.

However, these materials are chemically synthesized materials, and the process for manufacturing these materials may pollute environments. In addition, almost all of these materials are not biodegradable. Hence, when electronic devices are discarded, an additional waste treatment has to be performed to avoid further environmental pollution.

More and more countries around the world pay attention to the problems of environmental pollution. If natural and biodegradable dielectric materials can be developed and applied to electronic devices, not only can the waste treatment for discarded electronic devices be simplified, but also the purpose of environmental protection can be achieved.

In addition, flexible electronic devices are gradually being developed due to their lightness and portability. Examples of flexible electronic devices can be flexible display devices, solar cells, and electronic papers. In addition, roll-to-roll processes can be used for manufacturing flexible electronic devices, so these processes have large potential for commercial production. However, substrates or carrier boards used in flexible electronic devices are almost plastic substrates, which cannot endure high temperature producing processes. Hence, it is desirable to provide dielectric materials which can be used to form dielectric layers on plastic substrates at low temperature, for manufacturing flexible electronic devices.

### SUMMARY OF THE INVENTION

The object of the present invention is to provide a circuit board, which is a circuit board manufactured with a novel dielectric material.

Another object of the present invention is to provide a method for manufacturing a circuit board, which can produce a circuit board through a cheap and convenient process.

To achieve the object, the dielectric layer of the circuit board of the present invention is a protein dielectric layer. Hence, the circuit board of the present invention comprises: a carrier board, wherein a first circuit layer is disposed on at least one surface thereof, and the first circuit layer comprises plural conductive pads; a protein dielectric layer disposed on the surface of the carrier board and the first circuit layer, wherein the protein dielectric layer has plural openings to expose the conductive pads; and a second circuit layer disposed on a surface of the protein dielectric layer, wherein the second circuit layer comprises plural first conductive vias, and each first conductive via is correspondingly formed in the opening and electrically connects to the conductive pad.

In addition, the present invention further provides a method for manufacturing the aforementioned circuit board, which comprises the following steps: (A) providing a carrier board, wherein a first circuit layer is formed on at least one surface thereof, and the first circuit layer comprises plural conductive pads; (B) forming a protein dielectric layer on the surface of the carrier board and the first circuit layer; (C) forming plural openings in the protein dielectric layer, wherein each opening penetrates through the protein dielectric layer and respectively corresponds to the conductive pads to expose the conductive pads; and (D) forming a second circuit layer on the protein dielectric layer, and forming plural first conductive vias in the openings, wherein the first conductive vias electrically connect to the conductive pads of the first circuit layer.

According to the circuit board and the method for manufacturing the same of the present invention, protein is used as a dielectric material to form a protein dielectric layer on the carrier board. The protein material used in the circuit board and the method for manufacturing the same of the present invention is natural protein, which is not only cheap and easily available, but also highly bio-degradable. Hence, when electronic devices are discarded, an additional waste treatment to the dielectric layer can be omitted. In addition, the protein used as a dielectric material is a natural material, so it can be considered as an environmental friendly material.

According to the method for manufacturing the circuit board of the present invention, the step (B) may further comprise the following steps: (B1) providing a protein solution; (B2) coating at least one surface of the carrier board with the protein solution; (B3) drying the protein solution coated on the carrier board to form a protein dielectric layer on at least one surface of the carrier board.

In addition, according to the method for manufacturing the circuit board of the present invention, the carrier board can be coated with the protein solution through any coating process generally used in the art, to form the protein dielectric layer. Examples of the coating process can be a spin coating process, a dip coating process, a roll coating process, and a printing process. In the method of the present invention, the protein dielectric layer can be formed through a solution process, which is quite simple and cheap. Hence, the method of the present invention can be applied to form a protein dielectric layer with a large area. Furthermore, the drying process of the step (B3) can be any process generally used in the art, such as an air-drying process or a baking process. In addition, if it is needed, the step (B) can be repeatedly performed to obtain a dielectric layer with a multi-layer structure, or a dielectric layer with a pre-determined thickness.

According to the circuit board and the method for manufacturing the same of the present invention, the material of the protein dielectric layer or the protein contained in the protein solution can be silk protein, collagen, hydrolyzed collagen, wool protein, soy protein, gelatin, milk multi-proteins, or protein extracted from hair. Preferably, the material of the protein dielectric layer or the protein contained in the protein solution is natural silk protein, hydrolyzed collagen extracted from natural products, natural wool protein, or gelatin. More preferably, the material of the protein dielectric layer or the protein contained in the protein solution is fibroin.

In addition, according to the circuit board and the method for manufacturing the same of the present invention, the material and the structure of the carrier board is not particularly limited, and can be an insulating substrate, or a substrate with plural circuit layers. Furthermore, when the circuit board of the present invention is applied to prepare a flexible electronic device, the carrier board can be a plastic substrate, or a substrate with plural circuit layer formed on a plastic matrix.

According to the method for manufacturing the circuit board of the present invention, the plural openings can be formed in the protein dielectric layer through oxygen-containing plasma in the step (C). The example of oxygen-containing plasma can be atmospheric pressure plasma, or vacuum plasma. Herein, the gas used in the oxygen-containing atmospheric pressure plasma can be helium (He) gas contained oxygen, or argon (Ar) gas contained oxygen. Preferably, the oxygen-containing plasma is atmospheric pressure plasma, since the device for generating atmospheric pressure plasma is much cheaper than that for generating vacuum plasma, and the process using atmospheric pressure plasma can be applied to processes for large area devices.

In addition, according to the circuit board and the method for manufacturing the same of the present invention, the material for forming the first conductive vias is not particularly limited, which can be any metal conductive materials generally used in the art, such as Au, Ag, Cu, Al, and Ni; or any metal oxide conductive materials generally used in the art, such as indium tin oxide (ITO), indium zinc oxide (IZO), aluminum zinc oxide (AZO), indium gallium zinc oxide (IGZO), and zinc oxide (ZnO). Preferably, the material of the first conductive vias is Au, Ag or Cu. In addition, the process for forming the first conductive vias is not particularly limited, and can be any processes generally used in the art, such as a thermal evaporation process, a sputtering process, a silver paste coating process, a copper paste coating process, an electroplating process, or an electroless plating process.

Furthermore, the method for manufacturing the circuit board of the present invention may further comprise a step (E) after the step (D): forming a build-up structure on the surface of the protein dielectric layer and the second circuit layer, wherein the built-up structure comprises: at least one dielectric layer, at least one third circuit layer, and plural second conductive vias, and parts of the second conductive vias electrically connect to the second circuit layer. Hence, the circuit board of the present invention may further comprise a built-up structure disposed on the surface of the protein dielectric layer and the second circuit layer, wherein the built-up structure comprises: at least one dielectric layer, at least one third circuit layer, and plural second conductive vias, and parts of the second conductive vias electrically connect to the second circuit layer. More specifically, the second conductive vias of the innermost third circuit layer of the build-up structure electrically connect to the second circuit layer.

Herein, the material of or the process for forming the dielectric layer and the second conductive vias can be the same as or different from the material of or the process for forming the protein dielectric layer or the first conductive vias. Preferably, the material of or the process for forming the dielectric layer and the second conductive vias are the same as the material of or the process for forming the protein dielectric layer or the first conductive vias. Hence, the material of the dielectric layer of the build-up structure can be silk protein, collagen, hydrolyzed collagen, wool protein, soy protein, gelatin, milk multi-protein, or protein extracted from hair. Preferably, the material of the dielectric layer of the build-up structure is natural silk protein, hydrolyzed collagen extracted from natural products, natural wool protein, or gelatin. More preferably, the material of the dielectric layer of the build-up structure is fibroin.

According to the circuit board and the method of the present invention, the outmost third circuit layer of the build-up structure may further comprise plural conductive pads. In addition, the method for manufacturing the circuit board of the present invention may further comprise a step (F) after the step (E): forming an insulating protective layer on an outmost surface of the build-up structure, wherein the insulating protective layer has insulating protective openings to expose the conductive pads. Hence, the circuit board of the present invention may further comprise an insulating protective layer disposed on an outmost surface of the build-up structure, wherein the insulating protective layer has insulating protective openings to expose the conductive pads. Herein, the material of the insulating protective layers used in the present invention can be any insulating materials generally used in the art, such as a solder mask.

In addition, according to the circuit board and the method for manufacturing the same of the present invention, a small amount of fillers may be contained in the protein dielectric layer or the dielectric layer to enhance the stability of the circuit board. Herein, the material of the fillers can be any material generally used in the art, such as polymer, ceramic, or polymer doped with ceramic powders. The examples of the material of the fillers can be polyvinyl alcohol (PVA), Ba₂O₄Ti, PZT, and amorphous hydrogenated carbon.

Other objects, advantages, and novel features of the invention will become more apparent from the following detailed description when taken in conjunction with the accompanying drawings.

### BRIEF DESCRIPTION OF THE DRAWINGS

FIGS. 1A-1E are cross-sectional perspective views showing the process for manufacturing a connection structure in Embodiment 1 of the present invention;

FIG. 2 is a perspective view showing a device for generating atmospheric pressure plasma used in Embodiment 1 of the present invention;

FIG. 3A is a figure obtained by line-scanning the connection structure with an Auger Electron Spectroscopy showing the N signal of a conductive via formed in a protein dielectric layer of Embodiment 1 of the present invention;

FIG. 3B is a figure obtained by line scanning with an Auger Electron Spectroscopy showing the Au signal of a conductive via formed in a protein dielectric layer of Embodiment 1 of the present invention;

FIG. 4 is a result showing the resistance of a connection structure formed in Embodiment 1 of the present invention;

FIG. 5 is a result showing the resistance of a connection structure formed in Embodiment 2 of the present invention;

FIG. 6 is a result showing the resistance of a connection structure formed in Embodiment 3 of the present invention;

FIG. 7 is a result showing the resistance of a connection structure formed in Embodiment 4 of the present invention;

FIG. 8 is a result showing the resistance of a connection structure formed in Embodiment 5 of the present invention;

FIG. 9 is a result showing the resistance of a connection structure formed in Embodiment 6 of the present invention;

FIG. 10 is a result showing the resistance of a connection structure formed in Embodiment 7 of the present invention; and

FIGS. 11A-11C are cross-sectional perspective views showing the process for manufacturing a circuit board in Embodiment 8 of the present invention.

### DETAILED DESCRIPTION OF THE PREFERRED EMBODIMENT

The present invention has been described in an illustrative manner, and it is to be understood that the terminology used is intended to be in the nature of description rather than of limitation. Many modifications and variations of the present invention are possible in light of the above teachings. Therefore, it is to be understood that within the scope of the appended claims, the invention may be practiced otherwise than as specifically described.

### Embodiment 1

### Connection Structure of Circuit Board Using Silk Fibroin as Dielectric Material

### Preparation of a Silk Solution

First, 10 wt % of an aqueous solution of Na₂CO₃ was provided and heated. When the solution was boiling, natural silk was added thereto, and the solution was kept boiling to remove sericin. Then, the silk without sericin was washed by deionized water to remove the alkali salt adhered on the silk. After a drying process, refined silk, i.e. fibroin, was obtained.

Next, the refined silk was added into 85 wt % of phosphoric acid (H₃PO₄) solution (20 ml), and the resulted solution was stirred until the refined silk was dissolved. Then, the phosphoric acid solution containing the refined silk was put into a membrane (Spectra/Por 3 membrane, molecular weight cutoff=14000). The dialysis process was performed for 3 days to remove the phosphoric acid. Finally, a filter paper was used to filter out impurities, and an aqueous solution of fibroin was obtained.

### Preparation of a Connection Structure of a Circuit Board

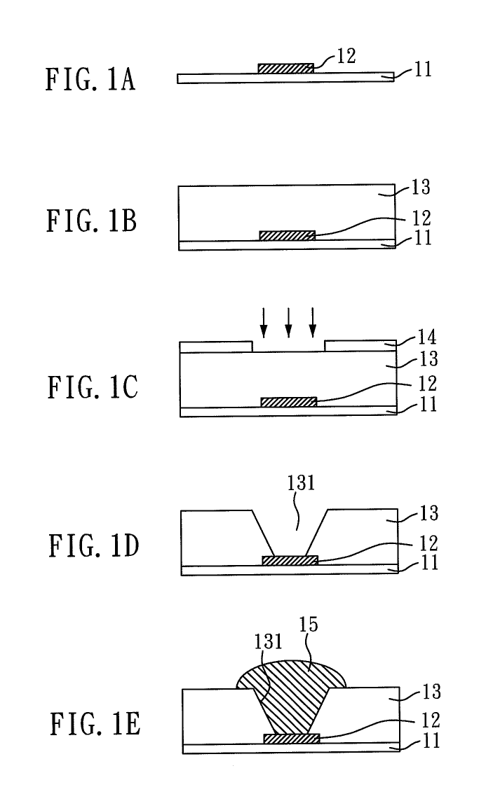

First, as shown in FIG. 1A, a carrier board 11 was provided, which is a plastic substrate. Then, a conductive pad 12 was plated on a surface of the carrier board 11, wherein the material of the conductive pad 12 was Au.

Next, the carrier board 11 having the conductive pad 12 formed thereon was dipped into the aforementioned silk solution for 15 mins to coat the carrier board 11 having the conductive pad 12 formed thereon with the silk solution. After the coating process, the carrier board 11 coated with the silk solution was dried at 60° C. to form a silk film, and the silk film was used as a protein dielectric layer 13, as shown in FIG. 1B. In addition, the coating process and the drying process can be performed several times to form a protein dielectric layer 13 with multi-layered structure and a pre-determined thickness, if it is needed.

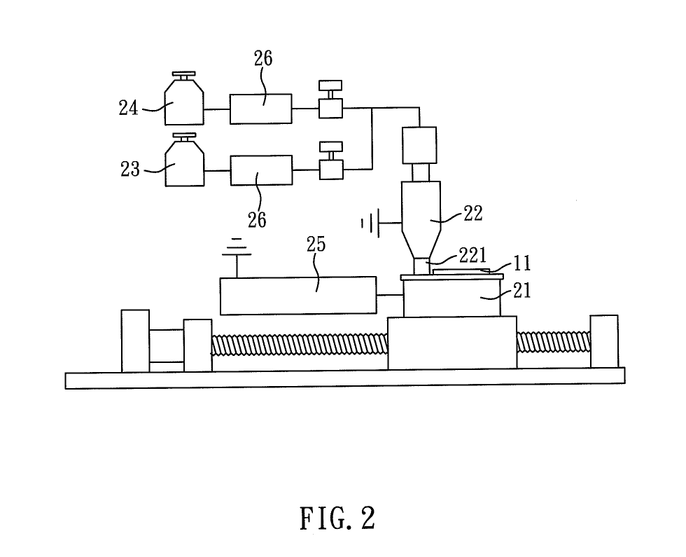

As shown in FIG. 1C, a patterned mask 14 was disposed on the protein dielectric layer 13. Then, an etching process was performed with an atmospheric pressure plasma treatment at room temperature, and the treating gas was oxygen-containing gas. The treating gas for the atmospheric pressure plasma treatment can be helium gas containing oxygen, or argon gas containing oxygen. A suitable flow rate of oxygen used in the atmospheric pressure plasma treatment can be 1-100 sccm, and a suitable flow rate of helium or argon can be 1-10 slm. In the present embodiment, the flow rate of oxygen was 30 sccm, and that of helium was 5 slm. In addition, the atmospheric pressure plasma treatment device used in the present embodiment is shown in FIG. 2, but the present invention is not limited thereto.

As shown in FIG. 2, the carrier board 11 with the mask disposed thereon shown in FIG. 1C was placed on a stage 21, wherein the stage 21 was used as an electrode. The oxygen supply device 23 and the helium supply device 24 were provided a mixture gas. The mixture gas was passed through a mass flow controller (MFC) 26, and then an air knife 22 as an electrode jetted out oxygen-containing plasma 221. The protein dielectric layer 13 (as shown in FIG. 1C) was etched by the oxygen-containing plasma 221 to form an opening 131 in the protein dielectric layer 13. The opening 131 was penetrated through the protein dielectric layer 13 to expose the conductive pad 12, as shown in FIG. 1D.

In the present embodiment, RF power supply device 25 provided energy to the stage 21, wherein the stage 21 was also used as an electrode, and the energy was 70 W. The mass flow controller 26 controlled the flow rate of oxygen supplied by the oxygen supply device 23 at 30 sccm, and the flow rate of helium supplied by the helium supply device 24 was 5 slm. In addition, the etching time of the plasma treatment was 10 mins.

The mask 14 was removed. Then, a first conductive via 15 was formed in the opening 131 of the protein dielectric layer 13 by plating Au or printing silver paste, and the first conductive via 15 was electrically connected to the conductive pad 12, as shown in FIG. 1E.

In order to confirm that the atmospheric pressure plasma treatment can etch the protein dielectric layer to form an opening in the protein dielectric layer, the opening of the protein dielectric layer, where the conductive via was not yet formed, was analyzed through an auger electron spectroscopy (AES) equipped with a scanning electron microscope (SEM).

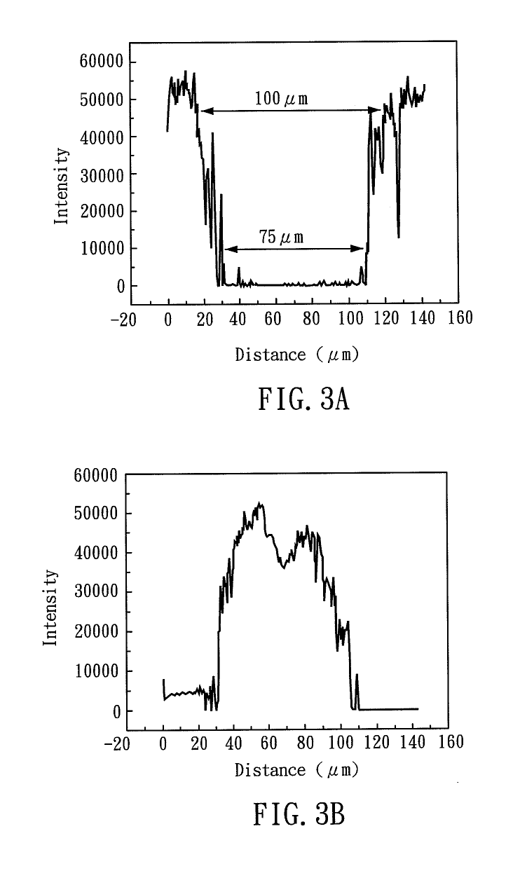

The SEM was used to locate the opening in the protein dielectric layer that was etched by the atmospheric pressure plasma treatment. Chemical signal of N and Au were then taken across the opening through the auger electron spectroscopy (AES) using line scan mode. Referring to FIG. 1D and FIG. 3A, the diameter of the opening 131 of the protein dielectric layer 13 was 100 μm, according to the result of the N signal of the protein dielectric layer 13 detected by the auger electron spectroscopy. Referring to FIG. 1D and FIG. 3B, Au signal was detected in the bottom of the opening 131 by the auger electron spectroscopy after the protein dielectric layer 13 was etched. Furthermore, the distribution of the Au signal shown in FIG. 3B corresponded and was contrary to that of the N signal shown in FIG. 3A. These results indicate that the opening 131 can be formed in the protein dielectric layer 13 by oxygen containing plasma using atmospheric pressure plasma treatment.

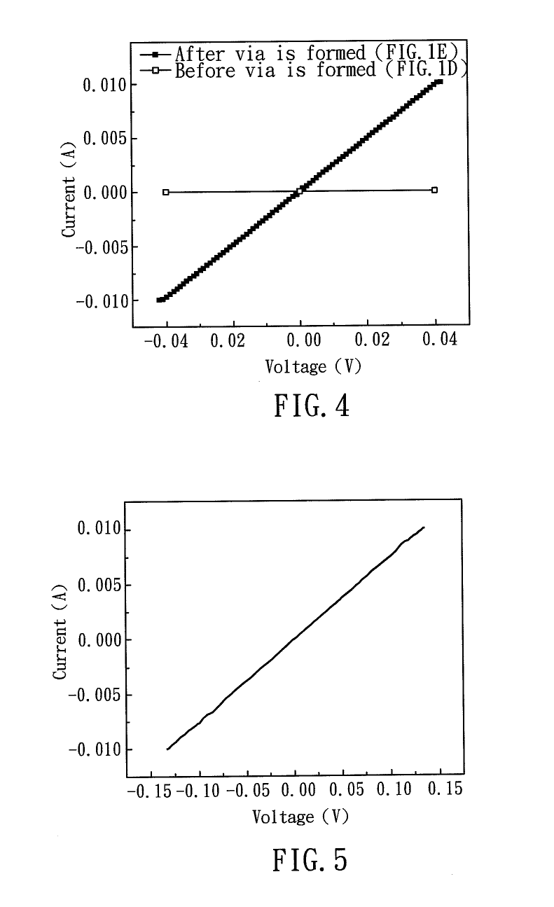

In addition, a semiconductor parameter analyzer (Agilent 4155C) was used to detect resistance before or after the first conductive via was formed in the present embodiment. As shown in FIG. 1D and FIG. 4, no current was detected in the opening 131 of the protein dielectric layer 13 before Au was plated or silver paste was printed. However, when Au was plated or silver paste was printed in the opening 131 of the protein dielectric layer 13 to form the first conductive via 15, a current was detected, as shown in FIG. 1E and FIG. 4. These results show that the silk fibroin can be used as a dielectric material to apply on the connection structure of the circuit board.

### Embodiment 2

### Connection Structure of Circuit Board Using Hydrolyzed Collagen as Dielectric Material

The connection structure of the circuit board and the method for manufacturing the same of the present embodiment were the same as those of Embodiment 1, except that the silk solution used in Embodiment 1 was substituted with a hydrolyzed collagen solution in the present embodiment. Hence, the material of the protein dielectric layer of the circuit board of the present embodiment is hydrolyzed collagen.

The hydrolyzed collagen used in the present embodiment was extracted from pigskin, and the process for preparing the hydrolyzed collagen solution was shown as follow.

Hydrolyzed collagen powders extracted from pigskin was obtained from Ken Le Ad Development CO., LTD. The hydrolyzed collagen powders were dissolved in de-ionized water to obtain a hydrolyzed collagen solution with a concentration of 3-4 wt %.

Here, the protein dielectric layer made from hydrolyzed collagen was also etched by oxygen containing plasma using atmospheric pressure plasma treatment at room temperature, and then Au was plated or silver paste was printed in the opening of the protein dielectric layer to form the first conductive via. The current signal of the first conductive via was detected according to the same method described in Embodiment 1. As shown in FIG. 5, a current can be detected. These results show that the hydrolyzed collagen can be used as a dielectric material to apply on the connection structure of the circuit board.

### Embodiment 3

### Connection Structure of Circuit Board Using Wool Keratin as Dielectric Material

The connection structure of the circuit board and the method for manufacturing the same of the present embodiment were the same as those of Embodiment 1, except that the silk solution used in Embodiment 1 was substituted with a wool keratin solution in the present embodiment, and the etching time of the plasma treatment was 5 mins. Hence, the material of the protein dielectric layer of the circuit board of the present embodiment is wool keratin.

The wool keratin used in the present embodiment was extracted from wool, and the process for preparing the wool keratin solution was shown as follow.

First, wool was washed in water for several times to remove dust and soil on the wool. Then, the clean wool was placed into an oven for 24 hrs to dry it completely. The dried wool was dipped into a solution containing alcohol and acetone (1:1) and stirred for 12 hrs, to remove the wool oil from the wool. After the wool oil was removed, the resulted wool was washed with de-ionized water, and dried for 24 hrs. After the aforementioned process, the pre-treatment of the wool was completed.

Next, the wool keratin in the wool was extracted through the following process. The dried wool without wool oil was dipped into a mixing solution containing urea, ethyl hydrosulfide and sodium dodecyl sulfate (SDS) for 12 hrs. Then, a mixing solution was heated to 50° C. to dissolve the wool. The un-dissolved wool was removed with a filter, and a dialysis process was performed on the filtrate containing wool protein to obtain a wool protein solution. Herein, the wool protein solution is a wool keratin solution.

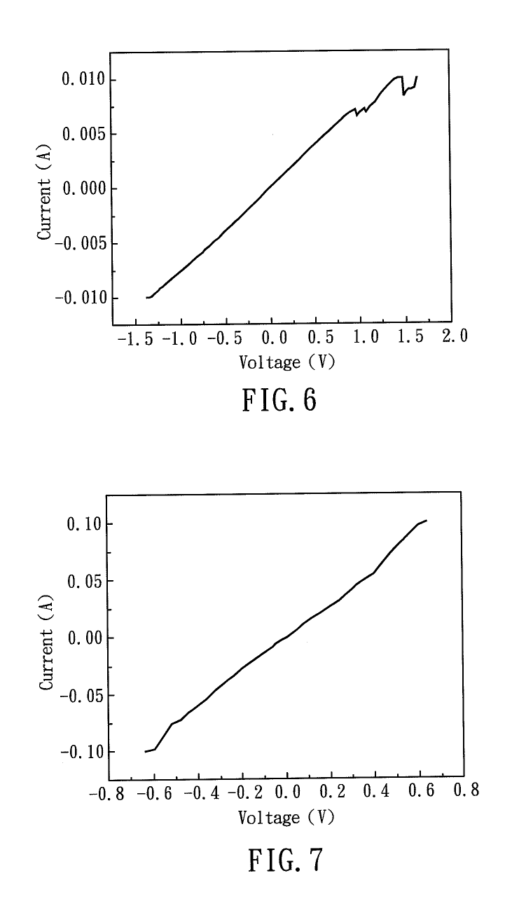

Here, the protein dielectric layer made from wool keratin was also etched by oxygen containing plasma using atmospheric pressure plasma treatment at room temperature, and then Au was plated or silver paste was printed in the opening of the protein dielectric layer to form the first conductive via. The current signal of the first conductive via was detected according to the same method described in Embodiment 1. As shown in FIG. 6, a current can be detected. These results show that the wool keratin can be used as a dielectric material to apply on the connection structure of the circuit board.

### Embodiment 4

### Connection Structure of Circuit Board Using Soy Protein as Dielectric Material

The connection structure of the circuit board and the method for manufacturing the same of the present embodiment were the same as those of Embodiment 1, except that the silk solution used in Embodiment 1 was substituted with a soy protein solution in the present embodiment. Hence, the material of the protein dielectric layer of the circuit board of the present embodiment is soy protein.

The soy protein used in the present embodiment was extracted from soymilk, and the process for preparing the soy protein solution was shown as follow.

Commercial soymilk was filtered with a filter paper to remove suspended particles, and then a soy protein solution was obtained.

Here, the protein dielectric layer made from soy protein was also etched by oxygen containing plasma using atmospheric pressure plasma treatment at room temperature, and then Au was plated or silver paste was printed in the opening of the protein dielectric layer to form the first conductive via. The current signal of the first conductive via was detected according to the same method described in Embodiment 1. As shown in FIG. 7, a current can be detected. These results show that soy protein can be used as a dielectric material to apply on the connection structure of the circuit board.

### Embodiment 5

### Connection Structure of Circuit Board Using Gelatin as Dielectric Material

The connection structure of the circuit board and the method for manufacturing the same of the present embodiment were the same as those of Embodiment 1, except that the silk solution used in Embodiment 1 was substituted with a gelatin solution in the present embodiment. The gelatin is also a kind of protein, and it is one hydrolyzed product from collagen. Hence, the material of the protein dielectric layer of the circuit board of the present embodiment is gelatin.

The gelatin used in the present embodiment was extracted from bone or connective tissue of animals. The process for preparing the gelatin solution was shown as follow.

Gelatin powder was obtained from NABISCO, INC. EAST HANOVER, N.J. 07936, USA, and dissolved in de-ionized water to obtain a gelatin solution.

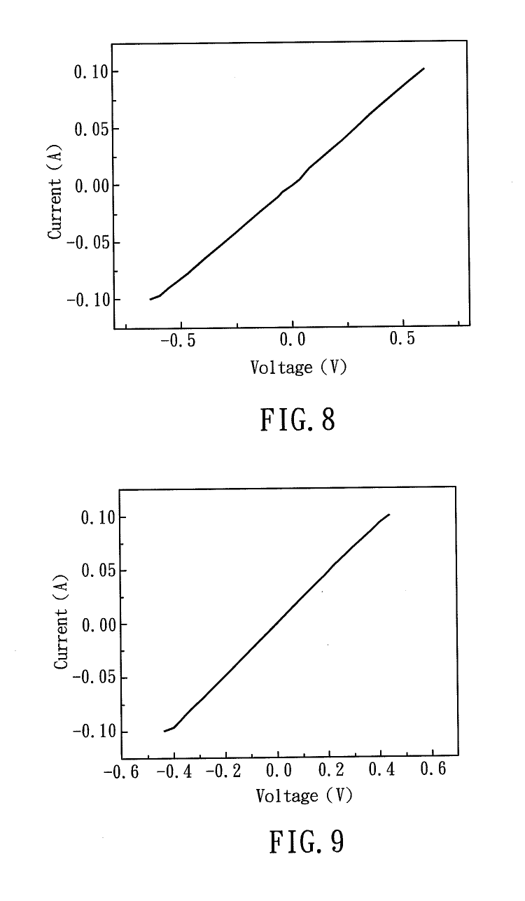

Here, the protein dielectric layer made from gelatin was also etched by oxygen containing plasma using atmospheric pressure plasma treatment at room temperature, and then Au was plated or silver paste was printed in the opening of the protein dielectric layer to form the first conductive via. The current signal of the first conductive via was detected according to the same method described in Embodiment 1. As shown in FIG. 8, a current can be detected. These results show that the gelatin can be used as a dielectric material to apply on the connection structure of the circuit board.

### Embodiment 6

### Connection Structure of Circuit Board Using Milk Multi-Proteins as Dielectric Material

The connection structure of the circuit board and the method for manufacturing the same of the present embodiment were the same as those of Embodiment 1, except that the silk solution used in Embodiment 1 was substituted with a milk multi-protein solution in the present embodiment. Hence, the material of the protein dielectric layer of the circuit board of the present embodiment is milk multi-protein.

The protein used in the present embodiment was extracted from milk, and the process for preparing the milk multi-protein solution was shown as follow.

Milk was purchased from Kuang Chuan Dairy CO., LTD, and the purchased milk was filtered with a filter paper to obtain a milk multi-protein solution. Herein, the main components in the milk multi-protein comprise whey and casein.

Here, the protein dielectric layer made from milk multi-protein was also etched by oxygen containing plasma using atmospheric pressure plasma treatment at room temperature, and then Au was plated or silver paste was printed in the opening of the protein dielectric layer to form the first conductive via. The current signal of the first conductive via was detected according to the same method described in Embodiment 1. As shown in FIG. 9, a current can be detected. These results show that milk multi-protein can be used as a dielectric material to apply on the connection structure of the circuit board.

### Embodiment 7

### Connection Structure of Circuit Board Using Silk Fibroin as Dielectric Material

The connection structure of the circuit board and the method for manufacturing the same of the present embodiment were the same as those of Embodiment 1, except that the opening in the protein dielectric layer was etched through vacuum plasma treatment. A suitable vacuum degree of vacuum plasma treatment is in a range from 1×10⁻³ Torr to 30×10³ Torr, and a suitable flow rate of oxygen used herein can be 1-100 sccm. In the present embodiment, the vacuum degree was 5×10⁻³ Torr, the flow rate of oxygen was 20 sccm, the energy of the RF power supply was 50 W, and the etching time of the plasma treatment was 5 mins.

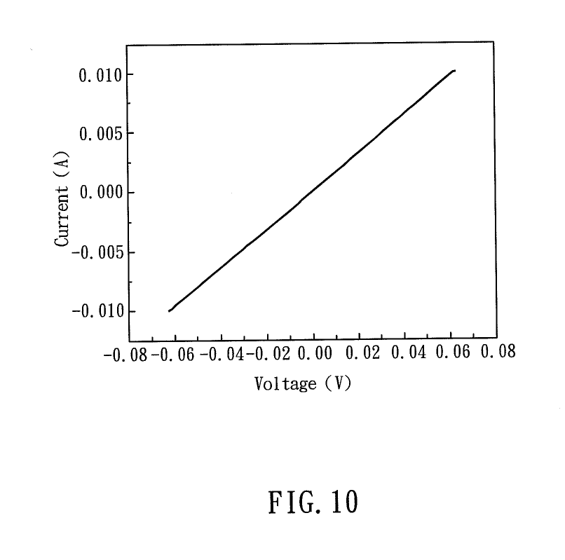

In addition, the current signal of the first conductive via was detected according to the same method described in Embodiment 1. As shown in FIG. 10, when Au was plated or silver paste was printed in the opening of the protein dielectric layer to form the first conductive via, a current can be detected.

### Embodiment 8

### Structure of Circuit Board

The present embodiment provides a circuit board manufactured with silk protein of Embodiment 1 as a dielectric material.

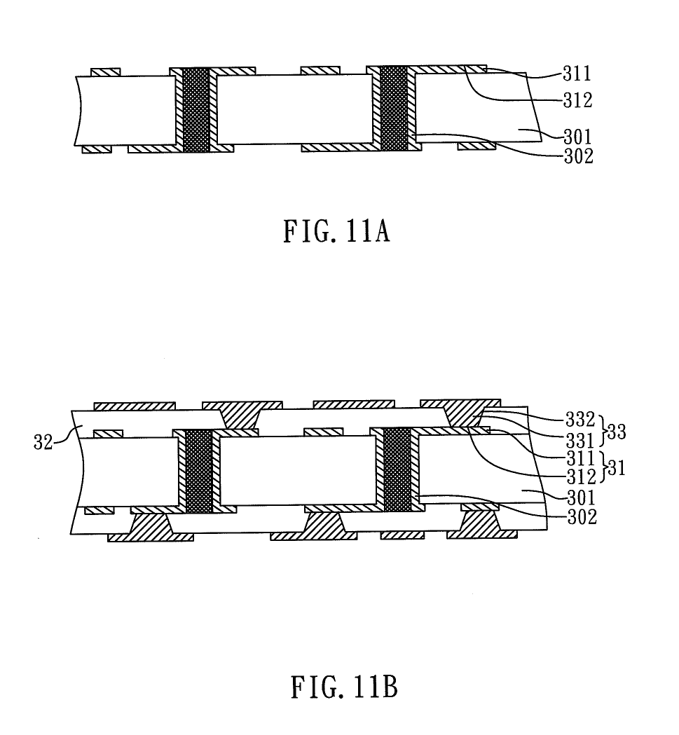

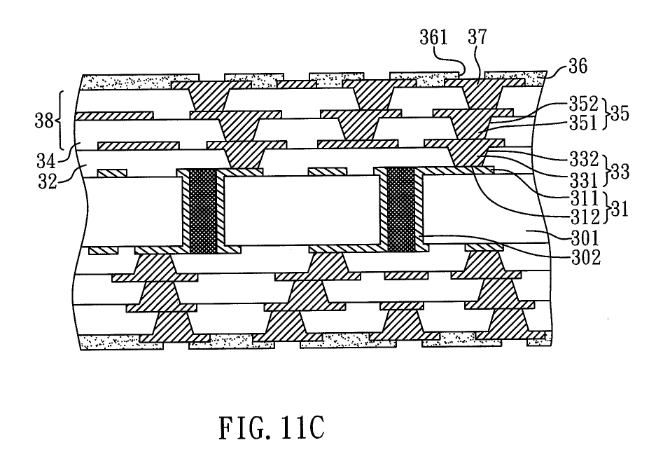

As shown in FIG. 11A, a carrier board 301 was provided, wherein a first circuit layer 31 was formed on at least one surface of the carrier board 301, and the first circuit layer 31 comprises circuit lines 311 with plural conductive pads 312. In addition, plated through holes 302 were also formed in the carrier board 301. The plated through holes 302 can electrically connect the first circuit layers 31 comprising the circuit lines 311 and the conductive pads 312 on two sides of the carrier board 301.

Next, as shown in FIG. 11B, at least one surface of the carrier board 301 was coated with a silk protein solution by the same method as illustrated in Embodiment 1, to form a protein dielectric layer 32 on at least one surface of the carrier board 301.

The protein dielectric layer 32 was etched by oxygen-containing plasma to form plural openings 332 in the protein dielectric layer 32 using the same method used in Embodiment 1. Each opening 332 penetrated through the protein dielectric layer 32 and corresponded to conductive pad 312 to expose the conductive pad 312, as shown in FIG. 11B.

Then, a second circuit layer 33 was formed on the surface of the protein dielectric layer 32. The second circuit layer 33 comprises first conductive vias 331, and each first conductive via 331 formed in and corresponded to the openings 332 to electrically connect to the conductive pad 312, as shown in FIG. 11B.

Finally, a conventional build-up process was performed to form a build-up structure 38 on the surface of the protein dielectric 32 and the second circuit layer 33, as shown in FIG. 11C. Herein, the built-up structure 38 comprised: at least one dielectric layer 34 with plural openings 352, at least one third circuit layer 35, and plural second conductive vias 351, and parts of the second conductive vias 351 electrically connected to the second circuit layer 33. In addition, the outmost third circuit layer 35 of the build-up structure 38 comprises plural conductive pads 37. The material of the dielectric layers 34 of the build-up structure 38 was also silk fibroin, and the openings 352 were also formed by oxygen-containing plasma.

In addition, according to the circuit board of the present embodiment, an insulating protective layer 36 was further formed on the outmost surface of the build-up structure 38, wherein the insulating protective layer 36 has insulating protective openings 361 to expose the conductive pads 37.

After the aforementioned process, as shown in FIG. 11C, the circuit board of the present embodiment comprised: a carrier board 301, wherein a first circuit layer 31 was disposed on at least one surface of the carrier board 301, and the first circuit layer 31 comprises plural conductive pads 312; a protein dielectric layer 32 disposed on the surface of the carrier board 301 and the first circuit layer 31, wherein the protein dielectric layer 32 has plural openings 332 to expose the conductive pads 312; and a second circuit layer 33 disposed on a surface of the protein dielectric layer 32, wherein the second circuit layer 33 comprised plural first conductive vias 331, and each first conductive via 331 was correspondingly formed in the opening 332 and electrically connected to the conductive pad 312. Herein, the material of the protein dielectric layer 32 was silk fibroin.

In addition, the circuit board of the present embodiment further comprised: a built-up structure 38 disposed on the surface of the protein dielectric layer 32 and the second circuit layer 33, wherein the built-up structure 38 comprised: at least one dielectric layer 34, at least one third circuit layer 35, and plural second conductive vias 351, and parts of the second conductive vias 351 electrically connect to the second circuit layer 33. Furthermore, the outmost third circuit layer 35 of the build-up structure 38 comprised plural conductive pads 37. The circuit board of the present embodiment further comprised an insulating protective layer 36 disposed on the outmost surface of the build-up structure 38, wherein the insulating protective layer 36 had insulating protective openings 361 to expose the conductive pads 37. Herein, the material of the dielectric layer 34 was also silk fibroin.

Although the present invention has been explained in relation to its preferred embodiment, it is to be understood that many other possible modifications and variations can be made without departing from the spirit and scope of the invention as hereinafter claimed.

What is claimed is:

1. A circuit board, comprising:
a carrier board, wherein a first circuit layer is disposed on at least one surface thereof, and the first circuit layer comprises plural conductive pads;
a protein dielectric layer disposed on the surface of the carrier board and the first circuit layer, wherein the protein dielectric layer has plural openings to expose the conductive pads; and
a second circuit layer disposed on a surface of the protein dielectric layer, wherein the second circuit layer comprises plural first conductive vias, and each first conductive via is correspondingly formed in the opening and electrically connects to the conductive pad.

2. The circuit board as claimed in claim 1, wherein the material of the protein dielectric layer is silk protein, collagen, hydrolyzed collagen, wool protein, soy protein, gelatin, milk multi-protein, or protein extracted from hair.

3. The circuit board as claimed in claim 2, wherein the silk protein is fibroin.

4. The circuit board as claimed in claim 1, wherein the carrier board is an insulating substrate, a substrate with plural circuit layers, or a plastic substrate.

5. The circuit board as claimed in claim 1, wherein the material of the first conductive vias is Au, Ag, Cu, Al, Ni, ITO, IZO, AZO, IGZO, or ZnO.

6. The circuit board as claimed in claim 1, further comprising a built-up structure disposed on the surface of the protein dielectric layer and the second circuit layer, wherein the built-up structure comprises: at least one dielectric layer, at least one third circuit layer, and plural second conductive vias, and parts of the second conductive vias electrically connect to the second circuit layer.

7. The circuit board as claimed in claim 6, wherein the material of the dielectric layer is silk protein, collagen, hydrolyzed collagen, wool protein, soy protein, gelatin, milk multi-protein, or protein extracted from hair.

8. The circuit board as claimed in claim 7, wherein the silk protein is fibroin.

9. The circuit board as claimed in claim 6, wherein the material of the second conductive vias is Au, Ag, Cu, Al, Ni, ITO, IZO, AZO, IGZO, or ZnO.

10. The circuit board as claimed in claim 6, wherein an outmost third circuit layer of the build-up structure comprises plural conductive pads.

11. The circuit board as claimed in claim 10, further comprising an insulating protective layer disposed on an outmost surface of the build-up structure, wherein the insulating protective layer has insulating protective openings to expose the conductive pads.

12. A method for manufacturing a circuit board, comprising the following steps:
(A) providing a carrier board, wherein a first circuit layer is formed on at least one surface thereof, and the first circuit layer comprises plural conductive pads;
(B) forming a protein dielectric layer on the surface of the carrier board and the first circuit layer;
(C) forming plural openings in the protein dielectric layer, wherein each opening penetrates through the protein dielectric layer and respectively corresponds to the conductive pads to expose the conductive pads; and
(D) forming a second circuit layer on the protein dielectric layer, and forming plural first conductive vias in the openings, wherein the first conductive vias electrically connect to the conductive pads of the first circuit layer.

13. The method as claimed in claim 12, wherein the openings are formed in the protein dielectric layer using oxygen-containing plasma in the step (C).

14. The method as claimed in claim 13, wherein the oxygen-containing plasma is atmospheric pressure plasma, or vacuum plasma.

15. The method as claimed in claim 12, wherein the material of the protein dielectric layer is silk protein, collagen, hydrolyzed collagen, wool protein, soy protein, gelatin, milk multi-protein, or protein extracted from hair.

16. The method as claimed in claim 15, wherein the silk protein is fibroin.

17. The method as claimed in claim 12, wherein the carrier board is an insulating substrate, a substrate with plural circuit layers, or a plastic substrate.

18. The method as claimed in claim 12, wherein the material of the first conductive vias is Au, Ag, Cu, Al, Ni, ITO, IZO, AZO, IGZO, or ZnO.

19. The method as claimed in claim 12, further comprising a step (E) after the step (D): forming a build-up structure on the surface of the protein dielectric layer and the second circuit layer, wherein the built-up structure comprises: at least one dielectric layer, at least one third circuit layer, and plural second conductive vias, and parts of the second conductive vias electrically connect to the second circuit layer.

20. The method as claimed in claim 19, wherein the material of the dielectric layer is silk protein, collagen, hydrolyzed collagen, wool protein, soy protein, gelatin, milk multi-protein, or protein extracted from hair.

21. The method as claimed in claim 20, wherein the silk protein is fibroin.

22. The method as claimed in claim 19, wherein the material of the second conductive vias is Au, Ag, Cu, Al, Ni, ITO, IZO, AZO, IGZO, or ZnO.

23. The method as claimed in claim 19, wherein an outmost third circuit layer of the build-up structure comprises plural conductive pads.

24. The method as claimed in claim 23, further comprising a step (F) after the step (E): forming an insulating protective layer on an outmost surface of the build-up structure, wherein the insulating protective layer has insulating protective openings to expose the conductive pads.
